(19) United States
(12) Patent Application Publication
(10) Pub. No.: US 2025/0125645 A1
(43) Pub. Date: Apr. 17, 2025

(54) APPARATUS FOR CONTROLLING CHARGING CURRENT OF BATTERY CELL AND METHOD THEREOF

(71) Applicants: HYUNDAI MOTOR COMPANY, Seoul (KR); Kia Corporation, Seoul (KR)

(72) Inventors: Woo Ju LEE, Hwaseong-si (KR); Jun Hee LEE, Bucheon-si (KR)

(21) Appl. No.: 18/443,642

(22) Filed: Feb. 16, 2024

(30) Foreign Application Priority Data
Oct. 11, 2023 (KR) 10-2023-0135263

(51) Int. Cl. H02J 7/00; H01M 10/44

(52) U.S. Cl. CPC H02J 7/007182; H01M 10/441; H02J 7/00714; H02J 7/007188

(57) ABSTRACT

Disclosed are an apparatus for controlling a charging current of a battery cell and a method thereof. The apparatus measures a potential of a reference electrode and a potential of an anode terminal within each battery ell for a plurality of battery cells, determines a difference between the potential of the reference electrode and the potential of the anode terminal as an anode potential, and determines a charging current of each battery cell based on a minimum value among anode potentials of the plurality of battery cells, thereby preventing lithium from being deposited on an anode surface of each battery cell.

### CROSS-REFERENCE TO RELATED APPLICATION

This application claims the benefit of priority to Korean Patent Application No. 10-2023-0135263, filed in the Korean Intellectual Property Office on Oct. 11, 2023, the entire contents of which are incorporated herein by reference.

### TECHNICAL FIELD

The present disclosure relates to a technology for controlling the charging current of each battery cell such that lithium is not deposited on the anode surface of each battery cell.

### BACKGROUND

Recently, as the demand for portable electronic products such as laptops, video cameras, portable phones, and the like has rapidly increased, and the development of electric vehicles, energy storage systems (ESS), robots, satellites, and the like has begun in earnest, research on high-performance batteries capable of repeated charging and discharging is actively underway.

Such a battery typically includes a plurality of battery cells, each of which includes a cathode current collector, an anode current collector, a separator, an active material, an electrolyte, and the like, and can be repeatedly charged and discharged through electrochemical reactions between components. In this case, in order to protect the plurality of battery cells from external shocks such as heat, vibration, and the like, a battery module may be formed by combining the plurality of battery cells into one. In order to systematically manage a plurality of battery modules, a battery system assembly (BSA) may be formed by using a plurality of battery modules, a battery management system (BMS), a power cutoff device, and a cooling device.

Currently commercialized batteries include nickel cadmium batteries, nickel hydrogen batteries, nickel zinc batteries, and lithium batteries. Among them, lithium batteries have less memory effect compared to nickel-based batteries, so they may be more freely charged and discharged. In addition, lithium batteries typically have relatively lower self-discharge rates and higher energy densities.

Although much research has been done on such batteries in terms of increasing capacity and density, it is also important to further improve their lifespan and safety. To this end, it is important to suppress the decomposition reaction with the electrolyte on the electrode surface and prevent overcharge and over-discharge.

Specifically, in extreme environments such as over-discharge, overcharge, overcurrent at extremely low temperatures, and overcurrent at extremely high temperatures, a phenomenon in which lithium is deposited on the anode surface of a battery cell due to a chemical side reaction (Li-plating) may occur. Lithium deposited on the surface of the anode can prevent the movement of lithium ions between the cathode and the anode, which not only reduces the energy efficiency of the battery but also causes battery cells to deteriorate.

In addition, lithium accumulated and deposited on the surface of the anode can form branch-shaped lithium crystals (hereinafter, referred to as dendrites). When the size of these dendrite increases, the separator, which is the core material of the battery, may be damaged. When the separator is damaged in such a manner, the cathode and anode may come into direct contact, causing an internal short circuit, and such an internal short circuit may cause ignition or explosion of the battery.

Generally, a charging strategy may be established to avoid conditions in which lithium is deposited on the anode surface of a battery cell, but because BSA operates based on temperature measurements of a specific battery cell, it may not be possible to prevent the formation of dendrites on the anode surface. Accordingly, development of technology that can help prevent dendrites from being formed on the anode surface of a battery cell is important.

The matters described in this background section are intended to promote an understanding of the background of the disclosure and may include matters that are not already known to those of ordinary skill in the art.

### SUMMARY

An aspect of the present disclosure provides an apparatus for controlling a charging current of a battery cell and a method thereof that can prevent lithium from being deposited on an anode surface of each battery cell by measuring a potential of a reference electrode and a potential of an anode terminal within each battery cell for a plurality of battery cells, determining a difference between the potential of the reference electrode and the potential of the anode terminal as an anode potential, and determining a charging current of each battery cell based on a minimum value among anode potentials of the plurality of battery cells.

Another aspect of the present disclosure provides an apparatus for controlling a charging current of a battery cell and a method thereof that can prevent lithium from being deposited on an anode surface of each battery cell by measuring a potential of a reference electrode and a potential of an anode terminal within each battery cell for a plurality of battery cells, determining a difference between the potential of the reference electrode and the potential of the anode terminal as an anode potential, estimating a lithium deposition rate of each battery cell based on the anode potential of each battery cell, and determining a charging current of each battery cell based on the maximum value among lithium deposition rates of the battery cells.

Still another aspect of the present disclosure provides an apparatus for controlling a charging current of a battery cell and a method thereof that can prevent lithium from being deposited on an anode surface of each battery cell by measuring a potential of a reference electrode and a potential of an anode terminal within each battery cell for a plurality of battery cells, determining a difference between the potential of the reference electrode and the potential of the anode terminal as an anode potential, estimating a lithium deposition rate of each battery cell based on the anode potential of each battery cell, and determining an accumulated amount of lithium deposition of each battery cell by using a lithium deposition rate of each battery cell, and determining a charging current of each battery cell based on the maximum value among accumulated amounts of lithium deposition of each battery cell.

Still another aspect of the present disclosure provides an apparatus for controlling a charging current of a battery cell and a method thereof that can prevent lithium from being deposited on an anode surface of each battery cell by measuring a potential of a reference electrode and a potential of an anode terminal within each battery cell for a plurality of battery cells, determining a difference between the potential of the reference electrode and the potential of the anode terminal as an anode potential, estimating a lithium deposition rate of each battery cell based on the anode potential of each battery cell, and determining an accumulated amount of lithium deposition of each battery cell by using a lithium deposition rate of each battery cell, selecting the minimum anode potential from anode potentials of battery cells, determining a first charging current corresponding to the minimum anode potential, selecting the maximum deposition rate from lithium deposition rates of the battery cells, determining a second charging current corresponding to the maximum deposition rate, selecting the maximum deposition amount from accumulated amounts of lithium deposition of the battery cells, determining a third charging current corresponding to the maximum deposition amount, and determining the minimum charging current among the first charging current, the second charging current, and the third charging current as a charging current of each battery cell.

The technical problems to be solved by the present disclosure are not limited to the aforementioned problems, and any other technical problems not mentioned herein will be clearly understood from the following description by those skilled in the art to which the present disclosure pertains. Also, it may be easily understood that the objects and advantages of the present disclosure may be realized by the units and combinations thereof recited in the claims.

According to an aspect of the present disclosure, an apparatus for controlling a charging current of a battery cell includes a voltage sensor that measures a potential, and a controller that determines a difference between the potential of the reference electrode and the potential of the anode terminal in each battery cell as an anode potential, and determines a first charging current of each battery cell based on a minimum value among anode potentials of the battery cells.

According to an implementation, the controller may control a charging current of each battery cell based on the first charging current to prevent or otherwise restrict lithium from being deposited on an anode surface of each battery cell.

According to an implementation, the controller may estimate a lithium deposition rate of each battery cell based on the anode potential of each battery cell, and determine a second charging current of each battery cell based on a maximum value among lithium deposition rates of the battery cells.

According to an implementation, the controller may control a charging current of each battery cell based on the second charging current to prevent or otherwise restrict lithium from being deposited on an anode surface of each battery cell.

According to an implementation, the controller may determine an accumulated amount of lithium deposition of each battery cell by using a lithium deposition rate of each battery cell, and determine a third charging current of each battery cell based on a maximum value among accumulated amounts of lithium deposition of each battery cell.

According to an implementation, wherein the controller may control the charging current of each battery cell based on the third charging current to prevent or otherwise restrict lithium from being deposited on an anode surface of each battery cell.

According to an implementation, the controller may determine a minimum charging current among the first charging current, the second charging current, and the third charging current as a new charging current of each battery cell.

According to an implementation, the plurality of battery cells may include a three-electrode battery cell.

According to an implementation, when the plurality of battery cells include at least one battery module, a leftmost battery cell and a rightmost battery cell within the at least one battery module may include three-electrode battery cells.

According to an implementation, when the plurality of battery cells include at least one battery module and the at least one battery module includes one battery pack, among at least one first battery module located on a leftmost side of the one battery pack and at least one second battery module located on a rightmost side of the one battery pack, a battery cell located on a leftmost side in the at least one first battery module and a battery cell located on a rightmost side in the at least one second battery module may include three-electrode battery cells.

According to another aspect of the present disclosure, a method of controlling a charging current of a battery cell includes measuring, by a voltage sensor, a potential of a reference electrode and a potential of an anode terminal within each battery cell for a plurality of battery cells, determining, by a controller, a difference between the potential of the reference electrode and the potential of the anode terminal in each battery cell as an anode potential, and determining, by the controller, a first charging current of each battery cell based on a minimum value among anode potentials of the plurality of battery cells.

According to an implementation, the method may further include controlling, by the controller, a charging current of each battery cell based on the first charging current to prevent or otherwise restrict lithium from being deposited on an anode surface of each battery cell.

According to an implementation, the method may further include estimating, by the controller, a lithium deposition rate of each battery cell based on the anode potential of each battery cell, and determining, by the controller, a second charging current of each battery cell based on a maximum value among lithium deposition rates of the battery cells.

According to an implementation, the method may further include controlling, by the controller, a charging current of each battery cell based on the second charging current to prevent or otherwise restrict lithium from being deposited on an anode surface of each battery cell.

According to an implementation, the method may further include determining, by the controller, an accumulated amount of lithium deposition of each battery cell by using a lithium deposition rate of each battery cell, and determining, by the controller, a third charging current of each battery cell based on a maximum value among accumulated amounts of lithium deposition of each battery cell.

According to an implementation, the method may further include controlling, by the controller, the charging current of each battery cell based on the third charging current to prevent or otherwise restrict lithium from being deposited on an anode surface of each battery cell.

According to an implementation, the method may further include determining, by the controller, a minimum charging current among the first charging current, the second charging current, and the third charging current as a new charging current of each battery cell.

According to an implementation, the plurality of battery cells may include a three-electrode battery cell.

According to an implementation, when the plurality of battery cells include at least one battery module, a leftmost battery cell and a rightmost battery cell within the at least one battery module may include three-electrode battery cells.

According to an implementation, when the plurality of battery cells include at least one battery module and the at least one battery module includes one battery pack, among at least one first battery module located on a leftmost side of the one battery pack and at least one second battery module located on a rightmost side of the one battery pack, a battery cell located on a leftmost side in the at least one first battery module and a battery cell located on a rightmost side in the at least one second battery module may include three-electrode battery cells.

### BRIEF DESCRIPTION OF THE DRAWINGS

The above and other objects, features, and advantages of the present disclosure will be more apparent from the following detailed description taken in conjunction with the accompanying drawings:

FIG. 1 is a block diagram illustrating an example apparatus for controlling a charging current of a battery cell according to an implementation of the present disclosure;

FIG. 2 is a diagram illustrating an example of a connection structure between a voltage sensor provided in an apparatus for controlling a charging current of a battery cell and each battery cell according to an implementation of the present disclosure;

FIG. 3 is a diagram illustrating an example of the structure of a three-electrode battery cell applied to an apparatus for controlling a charging current of a battery cell according to an implementation of the present disclosure;

FIG. 4 is a diagram illustrating a first example of a location of a three-electrode battery cell applied to an apparatus for controlling a charging current of a battery cell according to an implementation of the present disclosure;

FIG. 5 is a diagram illustrating a second example of a location of a three-electrode battery cell applied to an apparatus for controlling a charging current of a battery cell according to an implementation of the present disclosure;

FIG. 6 is a diagram illustrating a third example of a location of a three-electrode battery cell applied to an apparatus for controlling a charging current of a battery cell according to an implementation of the present disclosure;

FIG. 7 is a diagram illustrating an example performance analysis of an apparatus for controlling a charging current of a battery cell according to an implementation of the present disclosure;

FIG. 8 is a flowchart illustrating an example method of controlling a charging current of a battery cell according to an implementation of the present disclosure; and

FIG. 9 is a block diagram illustrating an example computing system for executing a method of controlling a charging current of a battery cell according to each implementation of the present disclosure.

### DETAILED DESCRIPTION

Hereinafter, implementations of the present disclosure will be described in detail with reference to the exemplary drawings.

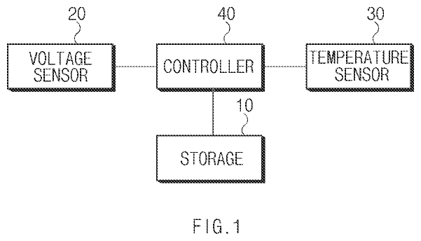

FIG. 1 is a block diagram illustrating an apparatus for controlling a charging current of a battery cell according to an implementation of the present disclosure.

As shown in FIG. 1, an apparatus for controlling a charging current of a battery cell according to an implementation of the present disclosure may include storage 10, a voltage sensor 20, a temperature sensor 30, and a controller 40. In this case, depending on an apparatus for controlling a charging current of a battery cell according to an implementation of the present disclosure, components may be combined with each other to be implemented as one, or some components may be omitted.

Regarding each component, the storage 10 may store various logic, algorithms and programs required in the processes of measuring a potential of a reference electrode and a potential of an anode terminal within each battery cell for a plurality of battery cells, determining a difference between the potential of the reference electrode and the potential of the anode terminal as an anode potential, and determining a charging current of each battery cell based on a minimum value among anode potentials of the plurality of battery cells.

In addition, the storage 10 may store various logic, algorithms and programs required in the processes of measuring a potential of a reference electrode and a potential of an anode terminal within each battery cell for a plurality of battery cells, determining a difference between the potential of the reference electrode and the potential of the anode terminal as an anode potential, estimating a lithium deposition rate of each battery cell based on the anode potential of each battery cell, and determining a charging current of each battery cell based on the maximum value among lithium deposition rates of the battery cells.

In addition, the storage 10 may store various logic, algorithms and programs required in the processes of measuring a potential of a reference electrode and a potential of an anode terminal within each battery cell for a plurality of battery cells, determining a difference between the potential of the reference electrode and the potential of the anode terminal as an anode potential, estimating a lithium deposition rate of each battery cell based on the anode potential of each battery cell, determining an accumulated amount of lithium deposition of each battery cell by using a lithium deposition rate of each battery cell, and determining a charging current of each battery cell based on the maximum value among accumulated amounts of lithium deposition of each battery cell.

In addition, the storage 10 may store various logic, algorithms and programs required in the processes of measuring a potential of a reference electrode and a potential of an anode terminal within each battery cell for a plurality of battery cells, determining a difference between the potential of the reference electrode and the potential of the anode terminal as an anode potential, estimating a lithium deposition rate of each battery cell based on the anode potential of each battery cell, determining an accumulated amount of lithium deposition of each battery cell by using a lithium deposition rate of each battery cell, selecting the minimum anode potential from anode potentials of battery cells, determining a first charging current corresponding to the minimum anode potential, selecting the maximum deposition rate from lithium deposition rates of the battery cells, determining a second charging current corresponding to the maximum deposition rate, selecting the maximum deposition amount from accumulated amounts of lithium deposition of the battery cells, determining a third charging current corresponding to the maximum deposition amount, and determining the minimum charging current among the first charging current, the second charging current, and the third charging current as a charging current of each battery cell.

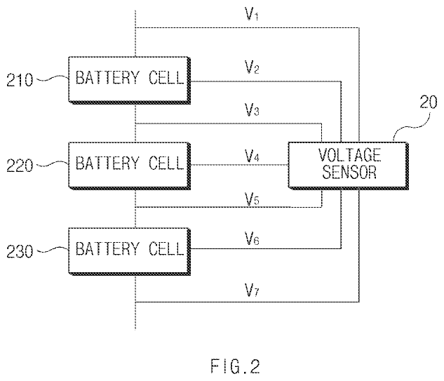

The voltage sensor 20 may measure the potential of a reference electrode, the potential of an anode terminal, and the potential of a cathode terminal within each battery cell for a plurality of battery cells. In this case, the voltage sensor 20 may be implemented as a plurality of voltage sensors to measure the potential of each battery cell. As shown in FIG. 2, the voltage sensor 20 may measure the potential of each battery cell.

FIG. 2 is a diagram illustrating an example of a connection structure between a voltage sensor provided in an apparatus for controlling a charging current of a battery cell and each battery cell according to an implementation of the present disclosure. To facilitate understanding, three battery cells are described as an example, but implementations are not limited thereto.

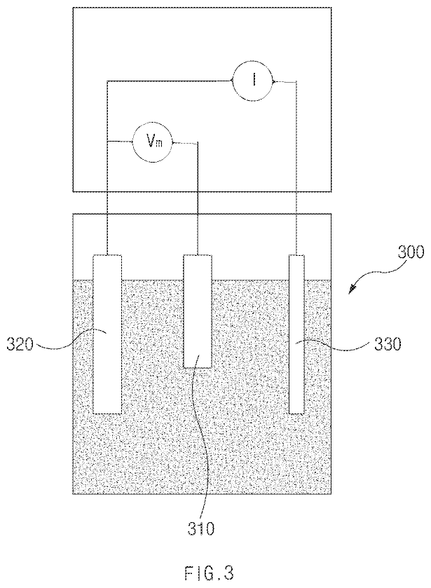

As shown in FIG. 2, the voltage sensor 20 may measure potentials V₁, V₂, V₃, V₄, V₅, V₆ and V₇ of battery cells 210, 220, and 230, respectively. In this case, reference numeral V₂ represents the potential of the reference electrode in the first battery cell 210, reference numeral V₄ represents the potential of the reference electrode in the second battery cell 220, and reference numeral V₆ represents the potential of the reference electrode in the third battery cell 230. In addition, each of the battery cells 210, 220, and 230 may be implemented as a three-electrode battery cell 300 as shown in FIG. 3.

FIG. 3 is a diagram illustrating an example of the structure of a three-electrode battery cell applied to an apparatus for controlling a charging current of a battery cell according to an implementation of the present disclosure.

As shown in FIG. 3, the three-electrode battery cell 300 applied to an apparatus for controlling a charging current of a battery cell according to an implementation of the present disclosure may include a reference electrode 310, an anode terminal 320, and a cathode terminal 330. Accordingly, the controller 40 may determine the difference between the potential of the reference electrode 310 and the potential of the anode terminal 320 as an anode potential, and determine the difference between the potential of the reference electrode 310 and the potential of the cathode terminal 330 as a cathode potential.

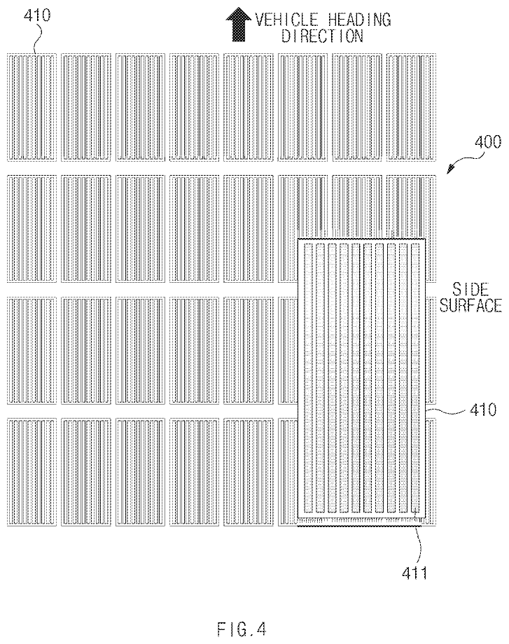

FIG. 4 is a diagram illustrating a first example of a location of a three-electrode battery cell applied to an apparatus for controlling a charging current of a battery cell according to an implementation of the present disclosure.

As shown in FIG. 4, a battery pack 400 may include 32 battery modules 410, and one battery module 410 may include 10 three-electrode battery cells 411.

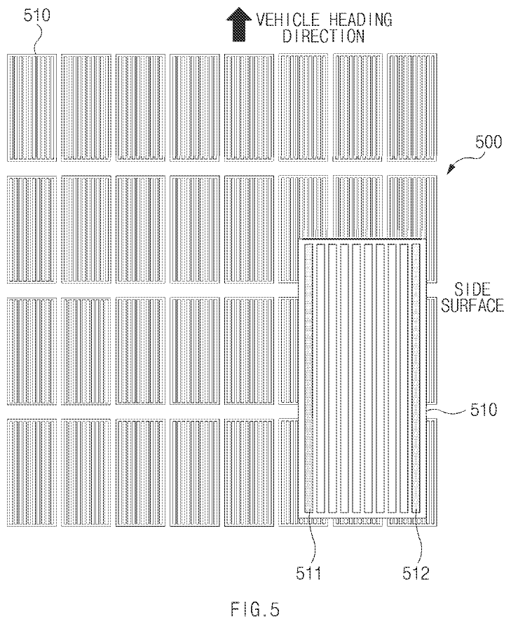

FIG. 5 is a diagram illustrating a second example of a location of a three-electrode battery cell applied to an apparatus for controlling a charging current of a battery cell according to an implementation of the present disclosure.

As shown in FIG. 5, each battery module 510 constituting a battery pack 500 may include 10 battery cells, where a first three-electrode battery cell 511 is located at the left end thereof, and a second three-electrode battery cell 512 may be located at the right end thereof. In addition, two-electrode (cathode and anode) battery cells are located at the remaining portions. Accordingly, the total number of three-electrode battery cells provided in the battery pack 500 having 32 battery modules 510 is 64.

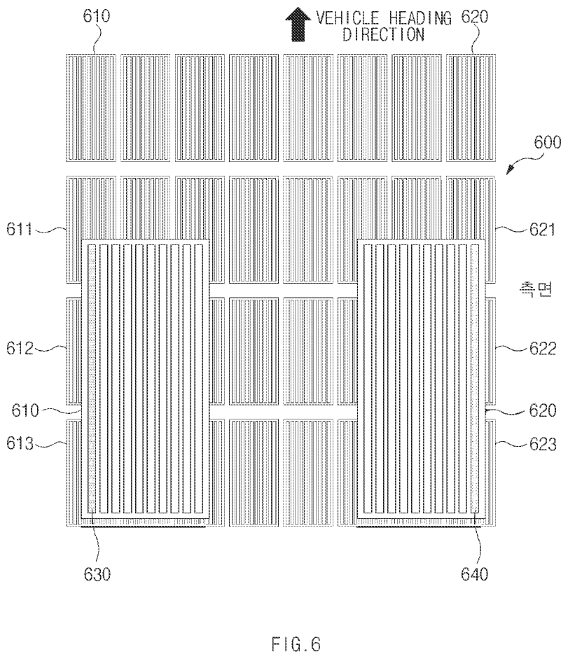

FIG. 6 is a diagram illustrating a third example of a location of a three-electrode battery cell applied to an apparatus for controlling a charging current of a battery cell according to an implementation of the present disclosure.

As shown in FIG. 6, a three-electrode battery cell may be located only in left four battery modules 610, 611, 612, and 613 and right four battery modules 620, 621, 622, and 623 constituting a battery pack 600.

In this case, a three-electrode battery cell 630 may be located on the leftmost side within the battery module 610, the three-electrode battery cell 630 may be located on the leftmost side within the battery module 611, the three-electrode battery cell 630 may be located on the leftmost side within the battery module 612, and the three-electrode battery cell 630 may be located on the leftmost side within the battery module 613.

In addition, a three-electrode battery cell 640 may be located on the rightmost side within the battery module 620, the three-electrode battery cell 640 may be located on the rightmost side within the battery module 621, the three-electrode battery cell 640 may be located on the rightmost side within the battery module 622, and the three-electrode battery cell 640 may be located on the rightmost side within the battery module 623.

The temperature sensor 30 may measure the temperature of the battery cell. In this case, the temperature sensor 30 may be implemented as a plurality of temperature sensors to measure the temperature of each battery cell for the plurality of battery cells 210, 220, and 230.

The controller 40 may perform overall control such that each component performs its function. The controller 40 may be implemented in the form of hardware or software, or may be implemented in a combination of hardware and software. Preferably, the controller 40 may be implemented as a microprocessor, but is not limited thereto.

As a first implementation, the controller 40 may measure the potential of the reference electrode 310 and the potential of the anode terminal 320 within each battery cell for the plurality of battery cells 210, 220, and 230, determine the difference between the potential of the reference electrode 310 and the potential of the anode terminal 320 as an anode potential, and determine a charging current of each battery cell based on the minimum value among the anode potentials of the battery cells.

In this case, the controller 40 may determine the charging current I₁ of each battery cell based on following Equation 1:

$${I}_{1} = I + {K}_{1} \times Min ( Vn ) , \qquad [ Equation 1 ]$$

where I₁ means the charging current at the current time, I means the charging current at the previous time, K₁ means the proportional control constant, and Min(Vn) means the minimum value among the anode potentials of battery cells.

As a second implementation, the controller 40 may measure the potential of the reference electrode 310 and the potential of the anode terminal 320 within each battery cell for the plurality of battery cells 210, 220, and 230, determine the difference between the potential of the reference electrode 310 and the potential of the anode terminal 320 as an anode potential, and estimate a lithium deposition rate of each battery cell based on the anode potential of each battery cell, and determine a charging current of each battery cell based on the maximum value among lithium deposition rates of the battery cells. In this case, the controller 40 may estimate the lithium deposition rate j₋^{Li} of each battery cell based on following Equation 2:

$${j}_{-}^{Li} = {i}_{0} ( exp ( \frac{{α}_{a} F}{RT} {η}_{-} ) - exp ( - \frac{{α}_{c} F}{RT} {η}_{-} ) ) , \qquad [ Equation 2 ]$$

where the first term on the right side represents the deposited amount of reversible lithium that is reduced during rest or discharge, and the second term on the right side represents the deposited amount of irreversible lithium that is not reduced during rest or discharge. In addition, j₋^{Li} represents the lithium deposition rate of the battery cell, i₀ is the exchange current density and is a fixed value (constant), αₐ is the charge transfer number of an anode and is a fixed value (constant), “F” represents the Faraday constant, R represents the gas constant, T represents the temperature value, and η₋ represents the anode potential.

Ultimately, in Equation 2, the variables are only the temperature T and the anode potential η₋, and the rest are all fixed values, so the controller 40 may estimate the lithium deposition rate of the battery cell when determining the anode potential η₋ based on the potential of the reference electrode 310 and the potential of the anode terminal 320 from the voltage sensor 20.

In addition, the controller 40 may determine the charging current I₂ of each battery cell based on following Equation 3:

$${I}_{2} = I - {K}_{2} \times Max ( {j}_{-}^{Li} ) , \qquad [ Equation 3 ]$$

where I₂ means the charging current at the current time point, “I” means the charging current at the previous time point, K₂ means the proportional control constant, and Max(j₋^{Li}) means the maximum lithium deposition rate of each battery cell.

As a third implementation, the controller 40 may measure the potential of the reference electrode 310 and the potential of the anode terminal 320 within each battery cell for the plurality of battery cells 210, 220, and 230, determine the difference between the potential of the reference electrode 310 and the potential of the anode terminal 320 as an anode potential, estimate a lithium deposition rate of each battery cell based on the anode potential of each battery cell, determine the accumulated amount of lithium deposition of each battery cell by using the lithium deposition rate of each battery cell, and determine a charging current of each battery cell based on the maximum value among lithium deposition rates of the battery cells.

In Equation 2, because the lithium deposition rate j₋^{Li} of the battery cell represents the amount of lithium deposited per second, the controller 40 may accumulate time to determine the accumulated lithium deposition amount of each battery cell. For example, when the amount of lithium deposited per second is 10, lithium was deposited for 2 seconds the first time, and lithium was deposited for 1 second the second time, lithium is deposited for 2 seconds the third time, the total accumulated amount of lithium deposited is 50.

In this case, the controller 40 may determine the charging current I₃ of each battery cell based on following Equation 4:

$${I}_{n} = {I}_{n - 1} - {K}_{3} \times Max ( {Q}_{-}^{Li} ) , \qquad [ Equation 4 ]$$

where I₃ means the charging current at the current time point, Iₙ₋₁ means the charging current at the previous time point, K₃ means the proportional control constant, and Max(Q₋^{Li}) means the maximum value among the accumulated lithium deposition amounts of each battery cell.

In a fourth implementation that integrates the first implementation, the second implementation and the third implementation, the controller 40 may select the minimum anode potential from anode potentials of battery cells, determining a first charging current I₁ corresponding to the minimum anode potential, select the maximum deposition rate from lithium deposition rates of the battery cells, determine a second charging current I₂ corresponding to the maximum deposition rate, select the maximum deposition amount from accumulated amounts of lithium deposition of the battery cells, determine a third charging current I₃ corresponding to the maximum deposition amount, and determine the minimum charging current among the first charging current, the second charging current, and the third charging current as a charging current I_{new} of each battery cell.

In this case, the controller 40 may determine the charging current I_{new} of each battery cell based on following Equation 5: [Equation 5]

$${I}_{new} = Min ( {I}_{1} , {I}_{2} , {I}_{3} )$$

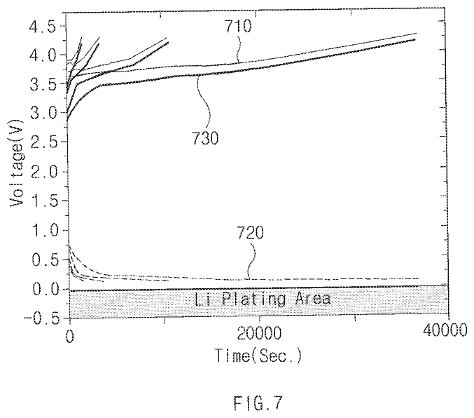

FIG. 7 is a diagram illustrating a performance analysis of an apparatus for controlling a charging current of a battery cell according to an implementation of the present disclosure.

In FIG. 7, the vertical axis represents voltage and the horizontal axis represents time. Reference numeral 710 represents the potential of the cathode, reference numeral 720 represents the potential of the anode, and reference numeral 730 represents the cell voltage representing the difference between the potential 710 of the cathode and the potential 720 of the anode. Phrase “Li Plating Area” refers to the area where lithium is deposited on the anode surface of the battery cell.

As shown in FIG. 7, it may be understood that the controller 40 controls the charging current of the battery cell, so that the potential 720 of the anode of the battery cell does not enter the “Li Plating Area.” Therefore, lithium does not deposited on the anode surface of the battery cell.

In some cases, an apparatus for controlling a charging current of a battery cell according to an implementation of the present disclosure may be implemented within a BMS, or the BMS may be implemented to perform a function of the apparatus for controlling a charging current of a battery cell. In addition, the functions of the voltage sensor 20 may be implemented to be performed by a cell monitoring unit (CMU).

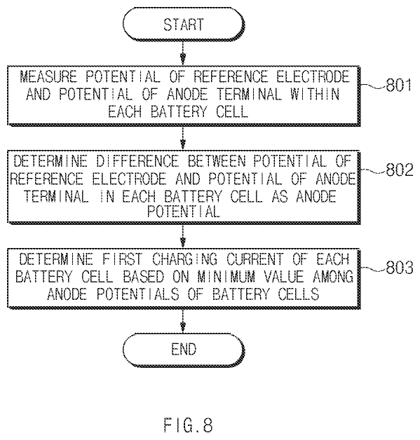

FIG. 8 is a flowchart illustrating a method of controlling a charging current of a battery cell according to an implementation of the present disclosure. FIG. 8 illustrates an example of a case in which an electric vehicle is being charged while being ready for departure, but implementations are not necessarily limited thereto.

First, as illustrated in 801, the voltage sensor 20 measures the potential of the reference electrode and the potential of the anode terminal within each battery cell for a plurality of battery cells.

Then, as illustrated in 802, the controller 40 determines the difference between the potential of the reference electrode and the potential of the anode terminal in each battery cell as an anode potential.

Then, as illustrated in 803, the controller 40 determines the first charging current of each battery cell based on the minimum value among the anode potentials of battery cells.

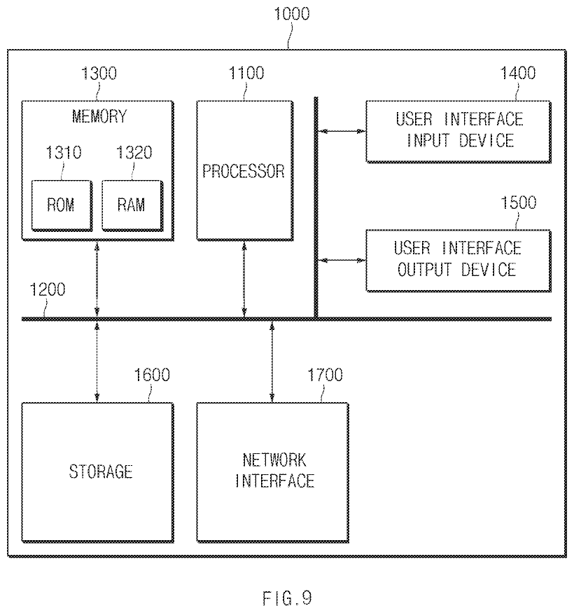

FIG. 9 is a block diagram illustrating a computing system for executing a method of controlling a charging current of a battery cell according to each implementation of the present disclosure.

Referring to FIG. 9, a method of controlling a charging current of a battery cell according to an implementation of the present disclosure described above may be implemented through a computing system 1000. The computing system 1000 may include at least one processor 1100, a memory 1300, a user interface input device 1400, a user interface output device 1500, storage 1600, and a network interface 1700 connected through a system bus 1200.

The processor 1100 may be a central processing device (CPU) or a semiconductor device that processes instructions stored in the memory 1300 and/or the storage 1600. The memory 1300 and the storage 1600 may include various types of volatile or non-volatile storage media. For example, the memory 1300 may include a ROM (Read Only Memory) 1310 and a RAM (Random Access Memory) 1320.

Accordingly, the processes of the method or algorithm described in relation to the implementations of the present disclosure may be implemented directly by hardware executed by the processor 1100, a software module, or a combination thereof. The software module may reside in a storage medium (that is, the memory 1300 and/or the storage 1600), such as a RAM, a flash memory, a ROM, an EPROM, an EEPROM, a register, a hard disk, solid state drive (SSD), a detachable disk, or a CD-ROM. The exemplary storage medium is coupled to the processor 1100, and the processor 1100 may read information from the storage medium and may write information in the storage medium. In another method, the storage medium may be integrated with the processor 1100. The processor 1100 and the storage medium may reside in an application specific integrated circuit (ASIC). The ASIC may reside in a user terminal. In another method, the processor 1100 and the storage medium may reside in the user terminal as an individual component.

According to the implementations of the present disclosure, it is possible to prevent or otherwise restrict lithium from being deposited on an anode surface of each battery cell by measuring a potential of a reference electrode and a potential of an anode terminal within each battery cell for a plurality of battery cells, determining a difference between the potential of a reference electrode and the potential of an anode terminal as an anode potential, and determining a charging current of each battery cell based on the minimum value among anode potentials of the plurality of battery cells.

Although exemplary implementations of the present disclosure have been described for illustrative purposes, those skilled in the art will appreciate that various modifications, additions and substitutions are possible, without departing from the scope and spirit of the disclosure. Therefore, the exemplary implementations disclosed in the present disclosure are provided for the sake of descriptions, not limiting the technical concepts of the present disclosure, and it should be understood that such exemplary implementations are not intended to limit the scope of the technical concepts of the present disclosure. The protection scope of the present disclosure should be understood by the claims below, and all the technical concepts within the equivalent scopes should be interpreted to be within the scope of the right of the present disclosure.

What is claimed is:

1. An apparatus for controlling a charging current, the apparatus comprising:
a voltage sensor configured to measure a potential of a reference electrode and a potential of an anode terminal within each battery cell among a plurality of battery cells; and
a controller configured to (i) determine a difference between the potential of the reference electrode and the potential of the anode terminal in each battery cell as an anode potential, and (ii) determine a first charging current of each battery cell based on a minimum value among anode potentials of the battery cells.

2. The apparatus of claim 1, wherein the controller is configured to control a charging current of each battery cell based on the first charging current to thereby restrict lithium from being deposited on an anode surface of each battery cell.

3. The apparatus of claim 1, wherein the controller is configured to (i) estimate a lithium deposition rate of each battery cell based on the anode potential of each battery cell, and (ii) determine a second charging current of each battery cell based on a maximum value among lithium deposition rates of the battery cells.

4. The apparatus of claim 3, wherein the controller is configured to control a charging current of each battery cell based on the second charging current to thereby restrict lithium from being deposited on an anode surface of each battery cell.

5. The apparatus of claim 3, wherein the controller is configured to (i) determine an accumulated amount of lithium deposition of each battery cell by using a lithium deposition rate of each battery cell, and (ii) determine a third charging current of each battery cell based on a maximum value among accumulated amounts of lithium deposition of each battery cell.

6. The apparatus of claim 5, wherein the controller is configured to control the charging current of each battery cell based on the third charging current to thereby restrict lithium from being deposited on an anode surface of each battery cell.

7. The apparatus of claim 5, wherein the controller is configured to determine a minimum charging current among the first charging current, the second charging current, and the third charging current as a new charging current of each battery cell.

8. The apparatus of claim 1, wherein the plurality of battery cells include a three-electrode battery cell.

9. The apparatus of claim 1, wherein, when the plurality of battery cells include at least one battery module, a leftmost battery cell and a rightmost battery cell within the at least one battery module include three-electrode battery cells.

10. The apparatus of claim 1, wherein, when the plurality of battery cells include at least one battery module and the at least one battery module includes one battery pack, among at least one first battery module located on a leftmost side of the one battery pack and at least one second battery module located on a rightmost side of the one battery pack, a battery cell located on a leftmost side in the at least one first battery module and a battery cell located on a rightmost side in the at least one second battery module include three-electrode battery cells.

11. A method of controlling a charging current, the method comprising:
measuring, by a voltage sensor, a potential of a reference electrode and a potential of an anode terminal within each battery cell among a plurality of battery cells;
determining, by a controller, a difference between the potential of the reference electrode and the potential of the anode terminal in each battery cell as an anode potential; and
determining, by the controller, a first charging current of each battery cell based on a minimum value among anode potentials of the plurality of battery cells.

12. The method of claim 11, further comprising:
controlling, by the controller, a charging current of each battery cell based on the first charging current to thereby restrict lithium from being deposited on an anode surface of each battery cell.

13. The method of claim 11, further comprising:
estimating, by the controller, a lithium deposition rate of each battery cell based on the anode potential of each battery cell; and
determining, by the controller, a second charging current of each battery cell based on a maximum value among lithium deposition rates of the battery cells.

14. The method of claim 13, further comprising:
controlling, by the controller, a charging current of each battery cell based on the second charging current to thereby restrict lithium from being deposited on an anode surface of each battery cell.

15. The method of claim 13, further comprising:
determining, by the controller, an accumulated amount of lithium deposition of each battery cell by using a lithium deposition rate of each battery cell; and
determining, by the controller, a third charging current of each battery cell based on a maximum value among accumulated amounts of lithium deposition of each battery cell.

16. The method of claim 15, further comprising:
controlling, by the controller, the charging current of each battery cell based on the third charging current to thereby restrict lithium from being deposited on an anode surface of each battery cell.

17. The method of claim 15, further comprising:
determining, by the controller, a minimum charging current among the first charging current, the second charging current, and the third charging current as a new charging current of each battery cell.

18. The method of claim 11, wherein the plurality of battery cells include a three-electrode battery cell.

19. The method of claim 11, wherein, when the plurality of battery cells include at least one battery module, a leftmost battery cell and a rightmost battery cell within the at least one battery module include three-electrode battery cells.

20. The method of claim 11, wherein, when the plurality of battery cells include at least one battery module and the at least one battery module includes one battery pack, among at least one first battery module located on a leftmost side of the one battery pack and at least one second battery module located on a rightmost side of the one battery pack, a battery cell located on a leftmost side in the at least one first battery module and a battery cell located on a rightmost side in the at least one second battery module include three-electrode battery cells.
